(19) United States
(12) Patent Application Publication
(10) Pub. No.: US 2006/0203181 A1
(43) Pub. Date: Sep. 14, 2006

(54) Copper wire or copper electrode protected by silver thin layer and liquid crystal display device having the wire or electrode

(76) Inventors: Hee Han, Daejeon (KR); Yong Joon Ha, Daejeon (KR)

Correspondence Address: CANTOR COLBURN, LLP, 55 GRIFFIN ROAD SOUTH, BLOOMFIELD, CT, 06002, US

(21) Appl. No.: 11/372,635

(22) Filed: Mar. 10, 2006

(30) Foreign Application Priority Data
Mar. 11, 2005 (KR) 10-2005-0020523

(51) Int. Cl. G02F 1/13

(52) U.S. Cl. 349/187

(57) ABSTRACT

Disclosed are a copper wire or a copper electrode protected by a silver thin layer coated on a surface of the copper wire or the copper electrode, and a method for fabricating the copper wire or the copper electrode. A liquid crystal display device and a method for manufacturing the same are also disclosed. After forming the copper wire or the copper electrode on the substrate, a silver thin layer is coated on the surface of the copper wire or the copper electrode, so that the silver thin layer protects copper. Thus, the copper has superior resistance against oxidation reaction or other unnecessary reactions, thereby improving the performance of the copper wire or the copper electrode.

This application claims the benefit of the filing date of Korean Patent Application No. 2005-0020523, filed on Mar. 11, 2005 in the Korean Intellectual Property Office, the disclosure of which is incorporated herein in its entirety by reference.

### TECHNICAL FIELD

The present invention relates to a copper wire or a copper electrode protected by a silver thin layer coated on a surface of the copper wire or the copper electrode. More particularly, the present invention relates to a liquid crystal display device having the copper wire or the copper electrode. If the silver thin layer is coated on the copper wire or the copper electrode formed on a substrate, the silver thin layer protects copper, so that the copper may have superior resistance against oxidation reaction or other unnecessary reactions. Thus, the performance of the copper wire or the copper electrode can be improved.

### BACKGROUND ART

Currently, most liquid crystal display (LCD) devices are easily fabricated and equipped with an inverted-staggered TFT (thin film transistor), which does not require a separate light-shielding layer for the TFT (see, FIG. 1).

An LCD device equipped with the inverted-staggered TFT generally includes two substrates formed with a plurality of components while facing each other and liquid crystal injected between the two substrates. One of the substrates, aligned at a relatively lower position, is formed with gate bus lines and data bus lines, which cross each other in the form of a matrix. In addition, pixel electrodes are provided in pixel areas defined by the gate bus lines and data bus lines so that the gate bus lines are electrically connected to the data bus lines by means of the pixel electrodes. That is, the inverted-staggered TFT generally includes a gate electrode formed on a glass substrate, a gate insulating layer formed on the entire surface of the glass substrate including the gate electrode, a semiconductor layer formed on the gate insulating layer provided on the gate electrode, source and drain electrodes formed on the semiconductor layer while being spaced from each other, and an ohmic contact layer interposed between the source and drain electrodes and the semiconductor layer. Meanwhile, the LCD device includes a TFT having the above-mentioned structure, a passivation layer formed on the entire surface of the substrate including the TFT, a contact hole for exposing the drain electrode, and a pixel electrode electrically connected to the drain electrode through the contact hole.

FIGS. 2a to 2d are sectional views illustrating the manufacturing procedure for the conventional LCD device.

In general, as shown in FIG. 2a, a copper layer is formed on a glass substrate 110 through a sputtering process. Then, the copper layer is selectively removed by performing a patterning process, such as a photolithography process, thereby forming a plurality of gate wires and a gate electrode 101.

Then, as shown in FIG. 2b, a gate insulating layer 102 is formed on the glass substrate 110 provided with the gate wires and the gate electrode 101. Herein, The gate insulating layer 102 is made from silicon nitride SiNx or silicon oxide SiOx having superior interfacial properties with respect to multi-crystalline silicon (a-Si), superior adhesion properties with respect to the gate electrode 101, and higher dielectric strength. After that, as shown in FIG. 2c, a semiconductor layer 103 is formed on the gate insulating layer 102 by using multi-crystalline silicon (a-Si).

Thereafter, an ohmic contact layer 104 is formed on the semiconductor layer 103 in order to obtain ohmic contact with respect to source and drain electrodes, which will be formed through following processes. In addition, as shown in FIG. 2d, a copper layer is formed on the entire surface of the glass substrate including the ohmic contact layer 104 and the copper layer is patterned, thereby forming data wiring lines crossing the gate wires and then forming a source electrode 105 and a drain electrode 106. Then, after coating a passivation layer 107 on the entire surface of the glass substrate including the source and drain electrodes 105 and 106, a predetermined portion of the passivation layer 107 is removed, thereby forming a contact hole 108 for exposing the drain electrode 106.

In addition, after depositing a transparent conductive layer on the entire surface of the glass substrate, a pixel electrode electrically connected to the drain electrode 106 through the contact hole 108 is formed by patterning the transparent conductive layer, thereby obtaining the conventional LCD device.

According to the conventional LCD device having the above structure, the electrodes and wires are made from copper. Such copper wires are regarded as next-generation wires to be replaced with conventional aluminum wires and performance of the copper wires has already been proven. Since copper has resistivity lower than that of aluminum, the copper can reduce the RC delay, enabling an IC to fast operate. In addition, since the copper has superior electromigration resistance, the copper can prevent a short circuit between metal circuits in the device. However, different from aluminum, copper is easily oxidized. For this reason, the copper electrode and copper wires are easily contaminated and have tendency to react with the insulating layer coated on the copper electrode and copper wires. In order to solve the above problem, studies are being actively performed in relation to semiconductor manufacturing processes while focusing on an ion implantation process for implanting ions onto a surface of the copper thin layer after the wiring process, a method of using a copper alloy thin layer, and a method of forming a stack structure including copper and other metals and heat-treating the stack structure.

Meanwhile, according to the conventional LCD device, the insulating layer or the passivation layer formed on the electrode or the wires is generally made from silicon compound. The silicon compound is formed on the substrate including the electrode and wires through a deposition process. At this time, SiH₄ of the silicon compound may react with copper, thereby degrading the performance of the electrode and wires.

In detail, the conventional LCD device includes a substrate and various thin layers are formed on the substrate through the deposition process. For instance, a metal layer and a transparent electrode are formed on the substrate through a sputtering process, and silicon and an insulating layer are formed on the substrate through a plasma enhanced chemical vapor deposition (PECVD) process.

According to the PECVD process, electrons excited by plasma collide with gas compound having a neutral phase, thereby dissolving the gas compound. In addition, gas ions created during the above process may interact with each other while thermal energy is being applied to the gas ions from the glass substrate, so that the gas ions are recombined, thereby forming the thin layers or thin films. At this time, the type of gas introduced into a reaction chamber may vary depending on the type of the thin layers to be formed on the substrate. In general, when it is necessary to form a hydrogenated amorphous silicon (a-Si:H) layer, SiH₄ or H₂ is used. In addition, if it is necessary to form a silicon nitride (SiNx) layer, mixture gas consisting of SiH₄, H₂, NH₃ and N₂ is employed. If it is necessary to form an n+a-Si:H layer, which is obtained by doping N-type impurity (phosphorous) into the hydrogenated amorphous silicon layer, PH₃ is added to the mixture gas.

When the silicon compound is deposited through the above manner, if the copper electrode or copper wires are not protected, SiH₄ used in the deposition process may react with copper, thereby creating silicide. Such silicide causes leakage current and breakdown, thereby malfunctioning the electrode and wires and degrading the reliability of the device.

In addition, since the surface of the copper thin layer has a hydrophobic property, photoresist residues may remain after a photoresist stripper process, which is performed after the pattern has been formed. Thus, it is necessary to remove the photoresist residues after forming the pattern.

### DISCLOSURE

### TECHNICAL PROBLEM

The present invention protects a copper electrode and copper wires so as to prevent SiH₄ from reacting with copper used in a deposition process, thereby preventing silicide from being created. Thus, leakage current and breakdown caused by the silicide may not occur, so the copper electrode and copper wires can be prevented from malfunctioning and the reliability of the device can be improved.

In addition, as mentioned above, the surface of the copper thin layer has the hydrophobic property, so photoresist residues may remain after the photoresist stripper process, which is performed after the pattern has been formed. In this regard, the present invention provides a method for easily removing the photoresist residues after the pattern has been formed.

### TECHNICAL SOLUTION

Inventors of the present invention have performed research and studies and found that it is possible to prevent silicide from being formed on a copper electrode or copper wires by coating a silver thin layer on a surface of the electrode or wires. In addition, if silver-substitutional solution is used when forming the silver thin layer, photoresist residues are effectively removed and the process is simplified, so that productivity may be improved.

Accordingly, an object of the present invention is to provide a method for forming a silver thin layer on a copper electrode or copper wires, an LCD device capable of improving the reliability thereof using the copper electrode and copper wires, and a method for manufacturing the LCD device.

Another object of the present invention is to provide a method for effectively removing photoresist residues remaining after a copper thin film has been patterned.

To accomplish the above objects, the present invention provides a copper electrode or copper wires protected by a silver thin layer coated on the copper electrode or copper wires.

In addition, the present invention provides a method for forming a copper electrode or copper wires including a step of forming a silver thin layer on copper. The present invention also provides a method for protecting a copper electrode or copper wires by forming a silver thin layer on the copper electrode or copper wires.

According to one aspect of the present invention, there is provided a method for fabricating an electrode or a wire, the method comprising the steps of: forming a copper thin layer on a surface of a substrate; forming the electrode or the wire by patterning the copper thin layer; and forming a silver thin layer on a surface of the electrode or the wire by immersing the substrate formed with the electrode or the wire in silver-substitutional solution. According to the above method, photoresist residues remaining after the patterning process for the copper thin film, which is performed in order to form the copper electrode or the copper wire, can be effectively removed.

According to another aspect of the present invention, there is provided a liquid crystal display device including a copper electrode and a copper wire protected by a silver thin layer. The liquid crystal display device includes-a substrate, a gate electrode, a source electrode, a drain electrode, an insulating layer formed on- the electrodes, a semiconductor layer, an ohmic contact layer, and a pixel electrode. At least one of the gate electrode, the source electrode and the drain electrode is formed at a surface thereof with the silver thin layer.

According to still another aspect of the present invention, there is provided a method for fabricating a liquid crystal display device, the method comprising the steps of: forming a gate wire and a gate electrode on a substrate by using copper; forming a silver thin layer on the gate wire and the gate electrode; forming an insulating layer on the silver thin layer; forming a channel layer on a predetermined region of the insulating layer; forming source and drain electrodes connected to both sides of the channel layer (semiconductor layer); forming a passivation layer on an entire surface of the substrate including the source and drain electrodes; and forming a pixel electrode on the passivation layer such that the pixel electrode is connected to the drain electrode.

### DESCRIPTION OF THE DRAWINGS

FIG. 1 is a schematic sectional view illustrating a conventional LCD device;

FIGS. 2a to 2d are sectional views illustrating the manufacturing procedure for a conventional LCD device;

FIG. 3 is a sectional view illustrating a silver thin layer formed on a copper thin layer according to one embodiment of the present invention;

FIGS. 4a to 4e are sectional views illustrating the manufacturing procedure for an LCD device according to one embodiment of the present invention;

FIGS. 5a and 5b are photographic views taken by an SEM, illustrating a surface and a section of a copper electrode, which is not undergone silver substitution, after forming a copper electrode and copper wires using a copper thin layer;

FIGS. 6a and 6b are photographic views taken by an SEM, illustrating a surface and a section of a silver thin layer, which is obtained by immersing a substrate in silver-substitutional solution, after forming a copper electrode and copper wires on the substrate;

FIGS. 7a and 7b are photographic views illustrating a surface of a copper electrode, which is not undergone silver substitution, after forming the copper electrode by patterning a copper thin layer;

FIGS. 8a and 8b are photographic views illustrating a surface of an electrode obtained by immersing the electrode in silver-substitutional solution after forming the electrode by patterning a copper thin layer;

FIG. 9a is a photographic view illustrating silicon nitride deposited on a surface of a copper electrode as an insulating layer;

FIG. 9b is a photographic view illustrating a silicon nitride layer deposited on an electrode after a surface of the copper electrode is replaced with a silver thin layer;

FIG. 10 is a view illustrating a short circuit occurring at a device due to dispersion of copper component into an insulating layer and oxidation of copper; and

FIG. 11 is a graph illustrating the result of an X-ray diffraction test for evaluating bonding force between an electrode and an insulating layer (silicon nitride layer).

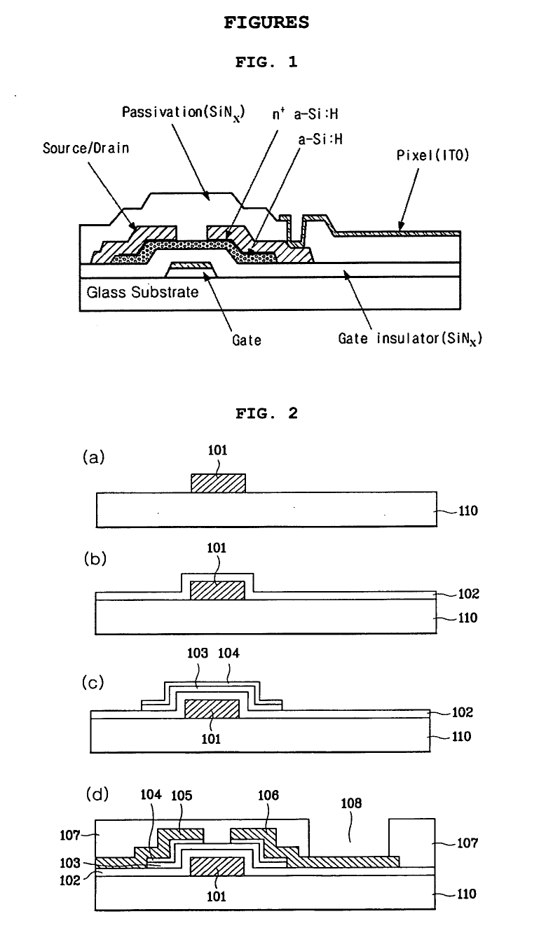

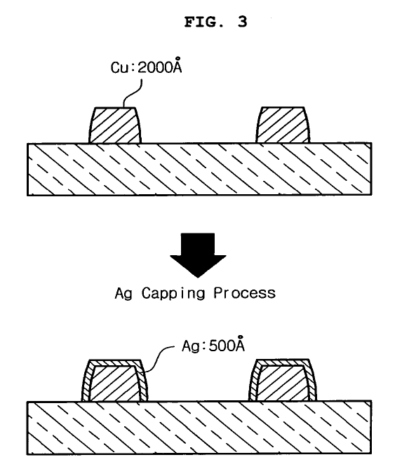

### BRIEF DESCRIPTION OF THE INDICATIONS

101, 201: gate electrode

102: insulating layer

202a: silver thin layer

202b: insulating layer

103, 203: semiconductor layer

104, 204: ohmic contact layer

105, 205: source electrode

106, 206: drain electrode

107, 207: passivation layer

108, 208: contact hole

209: pixel electrode

110, 210: glass substrate

### BEST MODE

Hereinafter, the present invention will be described in more detail.

According to a copper electrode or copper wires including a silver thin layer formed on copper, a thickness of the silver thin layer is generally 10 to 30 nm, and preferably 20 to 30 nm. If the thickness of the silver thin layer is less than 10 nm, the silver thin layer cannot sufficiently protect the copper electrode or copper wires. In addition, since the silver thin layer is formed based on the reduction potential difference, it is difficult to deposit the silver thin layer more than 30 nm. Thus, in general, a thickness of a barrier thin layer is equal to or less than 30 nm.

Preferably, an electrode protected according to the present invention includes a gate electrode of a semiconductor or a gate electrode and source/drain electrodes of an LCD device.

The present invention does not specially limit the method for forming the silver thin layer on the copper electrode, if it can form the silver thin layer on the copper electrode with a thickness of about 10 to 30 nm. Preferably, a dipping process using silver-substitutional solution (silver mirror reaction) can be used. That is, after forming the copper electrode and copper wires on a substrate, the substrate is immersed in silver-substitutional solution such that copper formed on a surface of the copper electrode or copper wires can be replaced with silver, thereby forming the silver thin layer on the surface of the copper electrode or copper wires.

The present invention does not specially limit the type and the manufacturing method of the silver-substitutional solution if it can replace a copper surface with a silver surface. In general, density of silver ions in the silver-substitutional solution is about 1 to 5M. Preferably, silver ion density in the silver-substitutional solution is about 1 to 2M, more preferably, 1.5 to 1.6M. Although the present invention does not specially limit the type of solvents, deionized water is preferably used as solvent. AgNO₃, KAg(CN)₂, etc., can be used as a silver ion carrier of the silver-substitutional solution. However, the present invention is not limited thereto. For instance, the silver-substitutional solution can be obtained by mixing AgNO₃, (NH₄)₂SO₄, and NH₄OH with deionized water or by mixing KAg(CN)₂ and KCN with deionized water.

The temperature of the silver-substitutional solution can be adjusted by taking the substitution speed and the surface state of the thin layer into consideration. If the temperature is less than 18° C., the substitution reaction is not easily performed due to the low temperature. If the temperature exceeds 100° C., water may be evaporated, so it is preferred to maintain the silver-substitutional solution at the temperature range of 18 to 100° C.

That is, the substrate formed with the copper electrode and copper wires protected by the silver thin layer can be obtained through the steps of forming the copper electrode or copper wires on the substrate, dipping the substrate in the silver-substitutional solution having the temperature of 18 to 100° C. for 10 to 30 seconds, cleaning the substrate using water, and drying the substrate.

When the silver-substitutional solution is used, the silver thin layer can be formed on copper, if the copper electrode or the copper wires formed by patterning the copper thin layer is immersed in the silver-substitutional solution. Thus, the copper electrode or copper wires and the silver thin layer can be continuously formed through one wet process.

In general, the gate electrode and source/drain electrodes used in the LCD device are immersed in etching solution, so that a metal layer is etched while forming a predetermined pattern. Then, a photoresist stripper process, which is a wet process, is performed so as to form a metal wiring layer. In a case of copper, since the copper has a hydrophobic property, photoresist residues may remain on the copper after the photoresist stripper process has been finished. In particular, according to an XPS analysis, organic compounds are found from the surface of the copper layer.

Conventionally, an UV cleaning process, which is a dry cleaning process, is performed in order to remove photoresist residues. The UV cleaning process removes the photoresist residues by burning the photoresist residues using UV light. However, since the present invention employs the silver-substitutional solution having storing reactivity, photoresist residues can be removed from the copper electrode together with copper formed on the surface of the copper electrode when the copper surface is replaced with the silver surface in the silver-substitutional solution.

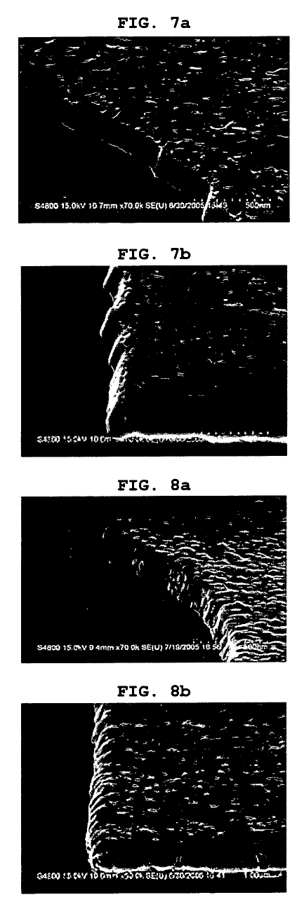

Therefore, according to the present invention, photoresist residues remaining after the patterning process can be effectively removed (see, FIG. 7b).

In the case of the copper electrode or copper wires formed on the surface thereof with the silver thin layer, an insulating layer may not react with copper even if the insulating layer is formed on the copper electrode or copper wires. Thus, the electric characteristics of the copper may not be degraded, so it is possible to protect the copper electrode or copper wires.

That is, if the surface of the copper electrode or copper wires is replaced with the silver thin layer, the copper electrode or copper wires represent superior resistance against oxidation reaction, so impurities created on the surface of the copper electrode or copper wires caused by oxidation can be significantly reduced. As a result, the copper electrode or copper wires may represent superior adhesion properties with respect to the silicon insulating layer, which is formed above the copper electrode or copper wires, and unnecessary reactions are restricted, so that it is possible to obtain the copper electrode or copper wires having superior quality and resistance characteristics. Particularly, silicide, which is derived from reaction between copper and SiH₄ when silicon compound is deposited on the copper electrode or copper wire, is prevented from being created, so that leakage current and breakdown caused by the silicide may not occur, thereby improving the reliability of the device.

### MODE FOR INVENTION

Hereinafter, an LCD device including a copper electrode and copper wires and a method for manufacturing the same will be described with reference to accompanying drawings.

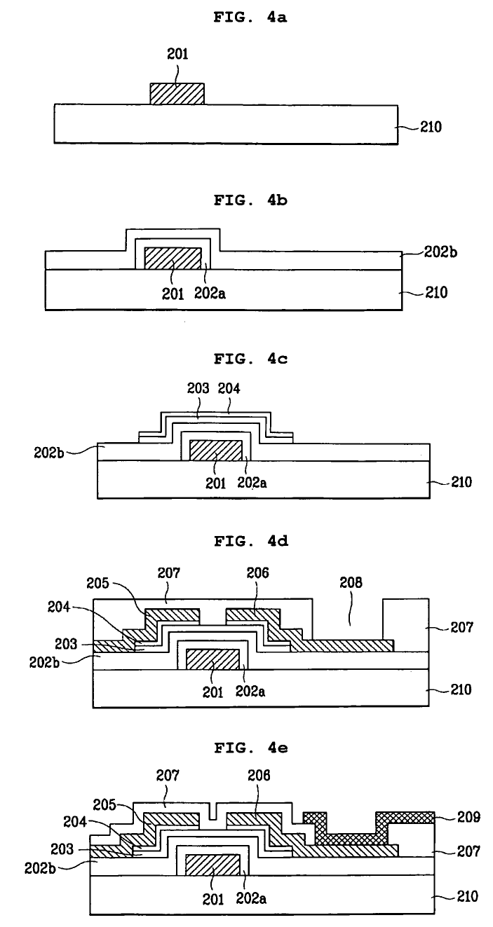

FIGS. 4a to 4e are sectional views illustrating the manufacturing procedure for the LCD device according to one embodiment of the present invention.

As shown in FIG. 4a, after depositing a copper metal layer on a glass substrate 210 through a sputtering process, the copper metal layer is patterned so as to form a plurality of gate wires and a gate electrode 201.

Then, as shown in FIG. 4b, after forming a silver thin layer 202a on the gate wires and the gate electrode 201, an insulating layer 202b made from silicon compound, which is inorganic substance having superior dielectric strength, is formed on the substrate 210 including the silver thin layer 202a. Preferably, the silver thin layer 202a is formed through a dipping process using silver-substitutional solution. That is, the glass substrate 210 formed with the gate wires and the gate electrode 201 is immersed in the silver-substitutional solution such that copper formed on the surface of the copper electrode or copper wires can be replaced with silver, thereby forming the silver thin layer on the surface of the copper electrode or copper wires. In this case, the silver thin layer can be simply formed through one process of dipping the glass substrate formed with the copper wires and the copper electrode into the silver-substitutional solution. In addition, photoresist residues remaining after the patterning process can be simultaneously removed through the dipping process, so the manufacturing process for the LCD device can be simplified.

In general, the insulating layer 202 is deposited on the substrate 210 through a PECVD process. At this time, the silver thin layer 202a restricts reaction between copper and SiH₄ used when depositing silicon nitride, thereby preventing silicide from being created.

After that, as shown in FIG. 4c, a semiconductor layer 203 and an ohmic contact layer 204, which are used as a channel of a thin film transistor, are formed on the insulating layer 202b. Preferably, the semiconductor layer 203 includes multi-crystalline silicon (a-Si) and the ohmic contact layer 204 includes n+a-Si:H doped with phosphorous.

Then, as shown in FIG. 4d, after depositing a copper metal layer on the entire surface of the substrate including the ohmic contact layer 204, the copper metal layer is patterned so as to form data wires crossing the gate wires and to form a source electrode 205 and a drain electrode 206. Preferably, the copper metal layer is deposited on the substrate through a sputtering process. The source and drain electrodes are also protected by the silver thin layer.

Then, after forming a passivation layer 207 on the entire surface of the substrate including the source and drain electrodes 205 and 206, a predetermined portion of the passivation layer 207 is partially removed in order to form a contact hole 208 for exposing the drain electrode 206. Preferably, the passivation layer 207 is formed through the PECVD process and mainly consists of organic substance having a low dielectric constant, such as BCB (Benzocyclobutene).

In addition, as shown in FIG. 4e, after depositing a transparent conductive layer on the entire surface of the substrate, the transparent conductive layer is patterned in order to form a pixel electrode 209, which is electrically connected to the drain electrode 206 through the contact hole 208 so as to apply voltage to liquid crystal, thereby obtaining the LCD device according to the present invention. The transparent conductive layer mainly includes indium tin oxide (ITO) and is formed through a sputtering process.

Hereinafter, the present invention will be described in detail with reference to embodiments, comparative examples and experimental examples, which are for illustrative purposes only and are not intended to limit the scope of the present invention.

### Embodiment 1

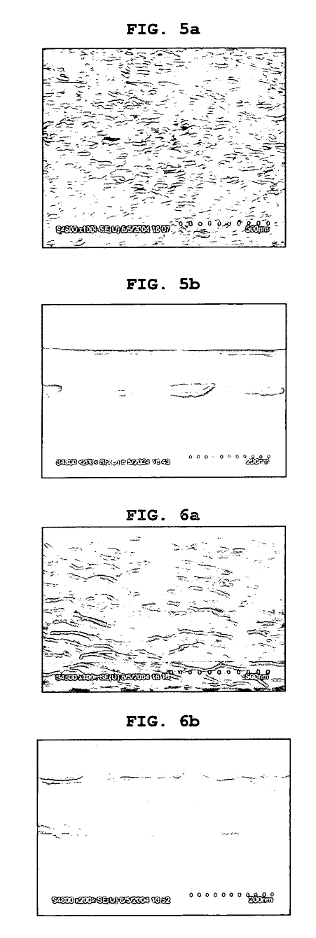

A copper metal layer is deposited on a glass substrate having a size of 11×11 cm through a sputtering process such that the copper metal layer has a thickness of about 200 nm. Then, the copper metal layer is patterned through a photoresist process, thereby forming a plurality of wires and electrodes (see, FIG. 5). At this time, the gate electrode and source/drain electrodes have the thickness of about 20 nm.

After that, silver-substitutional solution is prepared by mixing 0.26 g of AgNO₃, 6 g of (NH₄)₂SO₄, and 1 ml of NH₄OH₄ with 168 ml of deionized water. Then, the substrate formed with the wires and electrodes is immersed in the silver-substitutional solution for 10 seconds while maintaining the silver-substitutional solution at the temperature of 25° C.

Then, the substrate is washed using water and a drying process is carried out using a dry gun, thereby obtaining the substrate formed with the copper electrode and copper wires protected by the silver thin layer. The copper electrode and copper wires fabricated through the above procedure are shown in FIGS. 6 and 7.

According to the present embodiment, photoresist residues are removed by means of the silver-substitutional solution. That is, photoresist residues remaining on the electrode and wires are removed when the copper surface is replaced with the silver surface by means of the silver-substitutional solution having storing reactivity. This is shown in FIG. 7.

### Embodiment 2

Embodiment 2 is substantially identical to Embodiment 1, except that silver-substitutional solution is prepared by mixing KAg(CN)₂ and KCN with deionized water in order to form the copper electrode and copper wires protected by the silver thin layer.

### Embodiment 3

An insulating layer is formed on the electrode and wires fabricated through Embodiment 1 by depositing silicon nitride on the electrode and wires through the PECVD process, thereby obtaining a substrate including the electrode and wires protected by the insulating layer. Silicon nitride deposited on the electrode and wires has a thickness of about 200 nm.

### Embodiment 4

An LCD device having the electrode and wires is fabricated.

In detail, as shown in FIG. 4a, after depositing a copper metal layer on a glass substrate 210 through a sputtering process, the copper metal layer is patterned so as to form a plurality of gate wires and a gate electrode 201.

Then, silver-substitutional solution is prepared by mixing 0.26 g of AgNO₃, 6 g of (NH₄)₂SO₄, and 1 ml of NH₄OH₄ with 168 ml of deionized water. The substrate formed with the gate wires and the gate electrode 201 is immersed in the silver-substitutional solution for 10 seconds while maintaining the silver-substitutional solution at the temperature of 25° C., thereby forming the silver thin layer 202a. In addition, an insulating layer 202b made from silicon compound, which is inorganic substance having superior dielectric strength, is formed on the substrate 210 including the silver thin layer 202a (see, FIG. 4b). The insulating layer 202b is formed through a PECVD process.

After that, as shown in FIG. 4c, a semiconductor layer 203 and an ohmic contact layer 204, which are used as a channel of a thin film transistor, are formed on the insulating layer 202b. Preferably, the semiconductor layer 203 includes multi-crystalline silicon (a-Si) and the ohmic contact layer 204 includes n+a-Si:H doped with phosphorous.

Then, as shown in FIG. 4d, after depositing a copper metal layer on the entire surface of the substrate including the ohmic contact layer 204 through the sputtering process, the copper metal layer is patterned so as to form data wires crossing the gate wires and to form a source electrode 205 and a drain electrode 206.

In addition, after forming a passivation layer 207 on the entire surface of the substrate including the source and drain electrodes 205 and 206 through the PECVD process, a predetermined portion of the passivation layer 207 is partially removed in order to form a contact hole 208 for exposing the drain electrode 206. Preferably, the passivation layer 207 mainly consists of organic substance having a low dielectric constant, such as BCB (Benzocyclobutene).

Then, as shown in FIG. 4e, after depositing a transparent conductive layer on the entire surface of the substrate, the transparent conductive layer is patterned in order to form a pixel electrode 209, which is electrically connected to the drain electrode 206 through the contact hole 208 so as to apply voltage to liquid crystal, thereby obtaining the LCD device according to the present invention. The transparent conductive layer mainly includes indium tin oxide (ITO).

### COMPARATIVE EXAMPLE 1

According to Comparative Example 1, an insulating layer including silicon nitride is formed on the copper electrode and the copper wires in the same manner as Embodiment 3, except that the silver thin layer is not formed on the copper electrode and the copper wires.

### COMPARATIVE EXAMPLE 2

After forming the copper electrode and the copper wires, an organic insulating layer (first insulating layer) including BCB (Benzocyclobutene) is formed on the copper electrode and the copper wires without treating the copper electrode and the copper wires using the silver-substitutional solution. In addition, silicon nitride used in Embodiment 4 is formed on the organic insulating layer. Then, the LCD device is fabricated in the same manner as Embodiment 4.

<Surface Inspection and Void Inspection for the Electrode and Wires>

In order to check an external appearance, roughness, voids of the electrode fabricated according to Embodiment 3 and Comparative Example 1, the electrode is photographed by means of an SEM. FIGS. 7a and 7b are photographic views illustrating the surface of the copper electrode fabricated according to Comparative Example 1 before the insulating layer is formed, and FIGS. 8a and 8b are photographic views illustrating the surface of the copper electrode fabricated according to Embodiment 3.

Referring to FIGS. 7a and 7b, photoresist residues still remain on the copper surface after the photoresist process. In contrast, according to Embodiment 3 of the present invention, as shown in FIGS. 8a and 8b, photoresist residues can be completely removed from the copper surface by immersing the substrate in the silver-substitutional solution.

In the case of the electrode fabricated according to Embodiment 3, as shown in FIG. 8b, the lateral side of the electrode is linearly formed. In contrast, as shown in FIG. 7b, the lateral side of the electrode fabricated according to Comparative Example 1 is irregularly formed (line roughness).

If the lateral side of the copper electrode is irregularly formed as shown in FIG. 7b, voids may be formed when the insulating layer (silicon nitride) is formed on the copper electrode. Such voids cause stress to the thin layer, so copper of the copper electrode is dispersed into the insulating layer, thereby creating silicide.

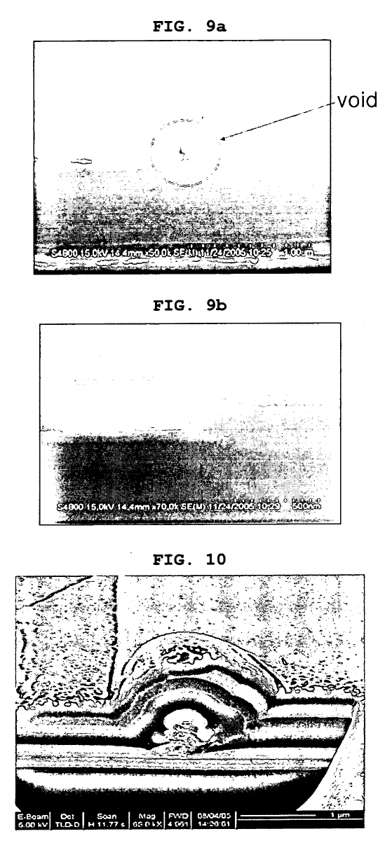

FIG. 9a is a photographic view illustrating silicon nitride deposited on the copper surface as an insulating layer (Comparative Example 1), and FIG. 9b is a photographic view illustrating a silicon nitride layer deposited on the electrode after the surface of the electrode is replaced with a silver thin layer (Embodiment 3). In the case of FIG. 9a, voids may be formed when depositing silicon nitride (SiNx) onto the copper surface due to the line roughness. If the voids are dispersed into the silicon nitride layer due to the stress of the thin layer, copper is easily oxidized at the silicon nitride layer.

FIG. 10 is a view illustrating a short circuit occurring at a device caused by dispersion of copper component into the insulating layer and oxidation of copper. If the copper electrode or copper wires are oxidized due to the copper component dispersed into the insulating layer, the reliability and yield rate of the device may be lowered. For instance, a defect called “GDS (gate drain short)” may occur in the electronic device, thereby lowering the yield rate in the copper wiring process.

Copper may rapidly react with silicon nitride, so silicide is easily created. However, since the reaction speed of silver with respect to silicon nitride corresponds to 1/100 of the reaction speed of copper, if the surface of the copper electrode or copper wires is replaced with the silver thin layer, an amount of silicide is significantly reduced. According to the present invention, the silver thin layer can be simply formed on the surface of the copper electrode or copper wires.

### EXPERIMENTAL EXAMPLE 1

After forming the insulating layer on the electrode and wires, electric characteristics of the electrode and wires were measured. In detail, sheet resistance of the electrode, which is formed on the substrate and is fabricated according to Comparative Example 1 and Embodiment 3 (see, FIGS. 5b and 6b), was measured five times using 4-point prove equipment available for sheet resistance measurement and a mean value of the sheet resistance was set as the sheet resistance of the electrode. The test result is shown in Table 1.

TABLE 1

| | Comparative | Embodiment 3 |
|---|---|---|
| Measurement Order | Example 1 (mΩ/cm) | (mΩ/cm) |
| 1^{st} | 116.1 | 95.6 |
| 2^{nd} | 113.8 | 96.1 |
| 3^{rd} | 113.9 | 95.3 |
| 4^{th} | 114.4 | 95.7 |
| 5^{th} | 114.5 | 96.2 |
| Average | 114.54 | 95.78 |

In addition, resistivity was also measured based on the sheet resistance.

As a result, the resistivity of the copper electrode fabricated according to Comparative Example 1 was represented as 2.29 μΩ·cm, but the resistivity of the copper electrode fabricated according to Embodiment 3 was reduced to 2.10 μΩ·cm. Thus, it can be understood from the above result that electric characteristics of the electrode and wires according to the present invention are improved.

As described above, if the surface of the copper electrode is replaced with the silver thin layer, the sheet resistance and resistivity can be reduced. In addition, if the resistivity is reduced, the response speed of the circuit can be improved, so the brightness and response speed of the LCD device can be improved when the above copper electrode and copper wires are applied to the LCD device.

### EXPERIMENTAL EXAMPLE 2

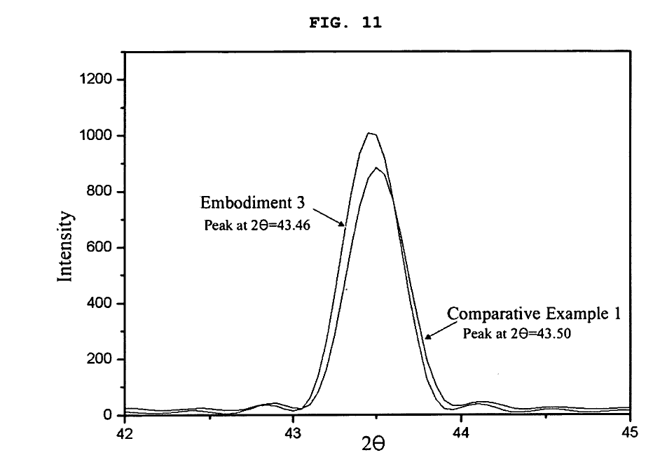

An X-ray diffraction test was performed so as to evaluate the bonding force between the electrode and the insulating layer (silicon nitride layer). The result is shown in FIG. 11.

According to ASTM data, in general, copper has a (111) peak at 2θ=43.295. However, in the electrode according to Comparative Example 1, in which the insulating layer is directly formed on copper, copper has a peak at 2θ=43.50. In addition, in the electrode according to Embodiment 3 of the present invention, in which the silver thin layer is formed on the copper electrode, copper has a peak at 2θ=43.46. That is, α2θ is 0.205 in the case of Comparative Example 1, and Δ2θ is 0.165 in the case of Embodiment 3.

When the silicon insulating layer is deposited on the copper electrode after the surface of the copper electrode is replaced with the silver thin layer, Embodiment 3 represents smaller variation of the (111) peak of copper as compared with that of Comparative Example 1, because the bonding force between the electrode and the silicon insulating layer is improved so that the stress applied thereto is reduced.

### INDUSTRIAL APPLICABILITY

As described above, when copper is used as a material for wires or an electrode, if the surface of the electrode or wires is replaced with the silver thin layer, the copper may have superior resistance against oxidation reaction, so the bonding force between the electrode and the insulating layer formed on the electrode is improved. Therefore, it is possible to obtain the electrode and wires having high quality and superior resistance characteristics. In particular, since SiH₄ used when depositing silicon compound on the copper electrode is prevented from reacting with copper, formation of silicide is restricted, so leakage current and breakdown caused by the silicide may not occur. Thus, the reliability of the device can be improved.

In addition, the electrode and wires fabricated according to the present invention have superior resistivity, so the brightness and response speed of the LCD device equipped with the electrode and wires can be improved. The present invention not only prevents copper from being dispersed, but also is applicable for the next-generation wiring technology.

We claim;:

1. A method for fabricating an electrode or a wire, the method comprising the steps of:
forming a copper thin layer on a surface of a substrate;
forming the electrode or the wire by patterning the copper thin layer; and
forming a silver thin layer on a surface of the electrode or the wire.

2. The method according to claim 1, wherein the step of forming the sliver thin layer includes a substep of immersing the substrate formed with the electrode or the wire in silver-substitutional solution, thereby forming the sliver thin layer on a surface of the copper thin layer, which has been patterned.

3. The method according to claim 2, wherein, in the step of forming the silver thin layer, the silver-substitutional solution is maintained at a temperature of about 18 to 100° C.

4. The method according to claim 2, wherein density of silver ions in the silver-substitutional solution is about 1 to 5M.

5. The method according to claim 2, wherein the silver-substitutional solution is prepared by using a silver ion carrier including at least one selected from the group consisting of AgNO₃ and KAg(CN)₂.

6. The method according to claim 2, wherein the substrate is immersed in the silver-substitutional solution for 10 to 30 seconds.

7. An electrode or a wire fabricated through a method according to claims 1.

8. An electrode made from copper, the electrode comprising:
a silver thin layer formed on a surface of the electrode.

9. The electrode according to claim 8, wherein the silver thin layer has a thickness of about 10 to 30 nm.

10. A liquid crystal display device comprising:
a substrate;
a gate electrode formed on the substrate;
a gate insulating layer formed on an entire surface of the substrate including the gate electrode;
a semiconductor layer formed on the gate insulating layer;
source and drain electrodes formed on the semiconductor layer while being spaced from each other by a predetermined distance;
an ohmic contact layer interposed between the source and drain electrodes and the semiconductor layer; and
a pixel electrode electrically connected to the drain electrode,
wherein a silver thin layer is formed on the surface of at least one of the gate electrode, the source electrode and the drain electrode.

11. A method for fabricating a liquid crystal display device, the method comprising the steps of:
forming a gate wire and a gate electrode on a substrate by using copper;
forming a silver thin layer on the gate wire and the gate electrode;
forming an insulating layer on the silver thin layer;
forming a channel layer on a predetermined region of the insulating layer;
forming source and drain electrodes connected to both sides of the channel layer;
forming a passivation layer on an entire surface of the substrate including the source and drain electrodes; and
forming a pixel electrode on the passivation layer such that the pixel electrode is connected to the drain electrode.

12. The method according to claim 11, wherein the step of forming the sliver thin layer on the gate wire and the gate electrode includes a substep of immersing the substrate formed with the gate wire and the gate electrode in silver-substitutional solution.

13. A method for preventing silicide from being formed on a copper wire or a copper electrode when fabricating the copper wire or the copper electrode coated with a silicon insulating layer, the method comprising a step of forming a silver thin layer on a surface of the copper wire or the copper electrode before the silicon insulating layer is coated on the copper wire or the copper electrode.
